(19) United States
(12) Patent Application Publication
(10) Pub. No.: US 2025/0194172 A1
(43) Pub. Date: Jun. 12, 2025

(54) SEMICONDUCTOR STRUCTURE AND METHOD FOR MANUFACTURING THE SAME

(71) Applicant: ENKRIS SEMICONDUCTOR, INC., Suzhou (CN)

(72) Inventor: Kai CHENG, Suzhou (CN)

(73) Assignee: ENKRIS SEMICONDUCTOR, INC., Suzhou (CN)

(21) Appl. No.: 18/966,399

(22) Filed: Dec. 3, 2024

(30) Foreign Application Priority Data
Dec. 7, 2023 (CN) 202311675719.0

(51) Int. Cl. H10D 62/10; H01L 21/266; H10D 30/01; H10D 30/47

(52) U.S. Cl. CPC H10D 62/102; H01L 21/266; H10D 30/017; H10D 30/481

(57) ABSTRACT

A semiconductor structure includes: a substrate, a channel layer and a barrier layer which are stacked sequentially, the channel layer and the barrier layer including a gate region, and a source region and a drain region which are located on two sides of the gate region; a p-type semiconductor layer, located in the gate region; a first hydrogen-rich layer, located on a side, close to the drain region, of the p-type semiconductor layer, a hydrogen concentration of the first hydrogen-rich layer being greater than a hydrogen concentration of the p-type semiconductor layer; a gate, a source and a drain, where the gate is located on a side, away from the substrate, of the p-type semiconductor layer, the source is located in the source region, and the drain is located in the drain region.

### CROSS-REFERENCE TO RELATED APPLICATIONS

The present disclosure claims priority to Chinese Patent Application No. 202311675719.0, filed on Dec. 7, 2023, the content of which is incorporated herein by reference in its entirety.

### TECHNICAL FIELD

The present disclosure relates to the field of semiconductor technologies, and in particular, to a semiconductor structure and a method for manufacturing the same.

### BACKGROUND

Compared with first generation semiconductor materials and second generation semiconductor materials, third generation semiconductor materials, especially Gallium Nitride (GaN)-based materials, have advantages such as large bandgap width, high breakdown field strength, high electron mobility and strong radiation resistance, and GaN-based High Electron Mobility Transistor (HEMT) devices have a great development potential in high-frequency high-power fields such as wireless communication base station, radar, automotive electronics, and the like.

In general, GaN-based HEMT devices are depletion-type field effect transistor, for example, a negative turn-on voltage needs to be used in a radio frequency microwave application, so that a circuit structure becomes complex and affects an anti-misstart protection function of the circuit, reducing security of the circuit. Therefore, it is necessary to develop an enhanced GaN-based HEMT device.

Common methods for implementing enhanced devices include trench gate technology, fluorine ion implantation technology and p-type gate technology. P-type gate technology is applied by adding a p-type GaN-based epitaxial layer between a gate metal and a barrier layer, reducing a barrier height of the barrier layer. Due to a conduction band difference between the p-type GaN-based epitaxial layer and the barrier layer, a conduction band of whole heterojunction is raised above a Fermi level, and Two-Dimensional Electron Gas (2DEG) at a channel below the gate is depleted to achieve enhancement. However, in the manufacturing process of a device, it is necessary to etch off the p-type GaN-based epitaxial layer between a gate and a source, and between a gate and a drain. However, it is difficult to control etching precision, so that etching damage is introduced, ultimately resulting in a reduce of output current density, an increase of a leakage current of the gate, and a reduce of the stability of the device.

### SUMMARY

In view of this, embodiments of the present disclosure provide a semiconductor structure and a method for manufacturing the same, to solve a technical problem of leakage current of a gate of a power device in conventional technologies.

According to an aspect of the present disclosure, an embodiment of the present disclosure provides a semiconductor structure, including: a substrate, a channel layer and a barrier layer which are stacked sequentially, the channel layer and the barrier layer including a gate region, and a source region and a drain region which are located on two sides of the gate region; a p-type semiconductor layer, located in the gate region; a first hydrogen-rich layer, located on a side, close to the drain region, of the p-type semiconductor layer, a hydrogen concentration of the first hydrogen-rich layer being greater than a hydrogen concentration of the p-type semiconductor layer; a gate, a source and a drain, where the gate is located on a side, away from the substrate, of the p-type semiconductor layer, the source is located in the source region and the drain is located in the drain region.

According to another aspect of the present disclosure, an embodiment of the present disclosure closure provides a method for manufacturing a semiconductor structure, including: epitaxially forming a channel layer and a barrier layer on a substrate sequentially, the channel layer and the barrier layer including a gate region, and a source region and a drain region which are located on two sides of the gate region; epitaxially forming a p-type semiconductor layer in the gate region; forming a first hydrogen-rich layer on a side, close to the drain region, of the p-type semiconductor layer, a hydrogen concentration of the first hydrogen-rich layer being greater than a hydrogen concentration of the p-type semiconductor layer; forming a gate, a source and a drain, where the gate is located on a side, away from the substrate, of the p-type semiconductor layer, the source is located in the source region, and the drain is located in the drain region.

### BRIEF DESCRIPTION OF THE DRAWINGS

FIG. 1 is a schematic structural diagram of a semiconductor structure according to an embodiment of the present disclosure.

FIG. 2 is a schematic structural diagram of a semiconductor structure according to another embodiment of the present disclosure.

FIG. 3 is a schematic structural diagram of a semiconductor structure according to another embodiment of the present disclosure.

FIG. 4 is a schematic structural diagram of a semiconductor structure according to another embodiment of the present disclosure.

FIG. 5 is a schematic structural diagram of a semiconductor structure according to another embodiment of the present disclosure.

FIG. 6 is a schematic structural diagram of a semiconductor structure according to another embodiment of the present disclosure.

FIG. 7 is a schematic structural diagram of a semiconductor structure according to another embodiment of the present disclosure.

FIG. 8 is a schematic structural diagram of a semiconductor structure according to another embodiment of the present disclosure.

FIG. 9 is a schematic structural diagram of a semiconductor structure according to another embodiment of the present disclosure.

FIG. 10 is a schematic flowchart of a method for manufacturing a semiconductor structure according to an embodiment of the present disclosure.

FIG. 11 is a schematic structural diagram of an intermediate structure formed during a manufacture process of a semiconductor structure according to an embodiment of the present disclosure.

FIG. 12 is a schematic structural diagram of an intermediate structure formed during a manufacture process of a semiconductor structure according to another embodiment of the present disclosure.

FIG. 13 is a schematic flowchart of manufacturing a first hydrogen-rich layer according to an embodiment of the present disclosure.

FIG. 14 is a schematic structural diagram of an intermediate structure formed during a manufacture process of a semiconductor structure according to another embodiment of the present disclosure.

FIG. 15 is a schematic structural diagram of an intermediate structure formed during a manufacture process of a semiconductor structure according to another embodiment of the present disclosure.

FIG. 16 is a schematic flowchart of manufacturing a first hydrogen-rich layer according to another embodiment of the present disclosure.

FIG. 17 is a schematic structural diagram of an intermediate structure formed during a manufacture process of a semiconductor structure according to another embodiment of the present disclosure.

FIG. 18 is a schematic structural diagram of an intermediate structure formed during a manufacture process of a semiconductor structure according to another embodiment of the present disclosure.

FIG. 19 is a schematic flowchart of manufacturing a first hydrogen-rich layer according to another embodiment of the present disclosure.

FIG. 20 is a schematic structural diagram of an intermediate structure formed during a manufacture process of a semiconductor structure according to another embodiment of the present disclosure.

FIG. 21 is a schematic structural diagram of an intermediate structure formed during a manufacture process of a semiconductor structure according to another embodiment of the present disclosure.

FIG. 22 is a schematic structural diagram of an intermediate structure formed during a manufacture process of a semiconductor structure according to another embodiment of the present disclosure.

### DETAILED DESCRIPTION OF THE EMBODIMENTS

The following clearly describes technical solutions in the embodiments of the present disclosure with reference to the accompanying drawings in the embodiments of the present disclosure. Apparently, the described embodiments are a part rather than all of the embodiments of the present disclosure.

In an enhanced device, when the device is in off-state, the leakage current of a gate is easy to occur, which reduce reliability of the device.

In order to solve above problem, the present disclosure provides a semiconductor structure and a method for manufacturing the same. The semiconductor structure includes: a substrate, a channel layer and a barrier layer which are stacked sequentially, the channel layer and the barrier layer including a gate region, and a source region and a drain regions which are located on two sides of the gate region; a p-type semiconductor layer, located in the gate region; a first hydrogen-rich layer, located on a side, close to the drain region, of the p-type semiconductor layer, a hydrogen concentration of the first hydrogen-rich layer being greater than a hydrogen concentration of the p-type semiconductor layer; a gate, a source and a drain. The gate is located on a side, away from the substrate, of the p-type semiconductor layer. The source is located in the source region. The drain is located in the drain region.

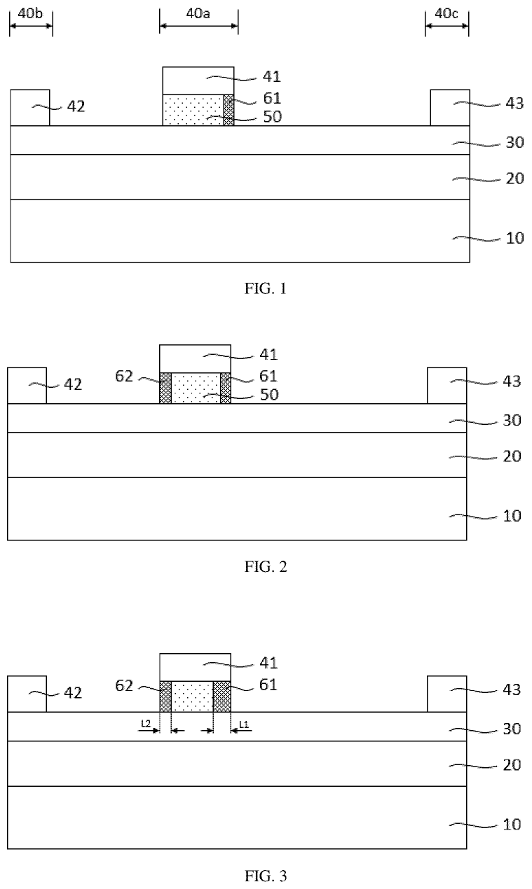

The following further illustrates a semiconductor structure and a method for manufacturing the same mentioned by the present disclosure with reference to FIG. 1 to FIG. 22.

FIG. 1 is a schematic structural diagram of a semiconductor structure according to an embodiment of the present disclosure. As shown in FIG. 1, the semiconductor structure includes: a substrate 10, a channel layer 20 and a barrier layer 30 which are stacked sequentially, the channel layer 20 and the barrier layer 30 including a gate region 40a, and a source region 40b and a drain region 40c which are located on two sides of the gate region 40a; a p-type semiconductor layer 50, located in the gate region 40a; a first hydrogen-rich layer 61, located on a side, close to the drain region 40c, of the p-type semiconductor layer 50, a hydrogen concentration of the first hydrogen-rich layer 61 being greater than a hydrogen concentration of the p-type semiconductor layer 50; and a gate 41, a source 42 and a drain 43. The gate 41 is located on a side, away from the substrate 10, of the p-type semiconductor layer 50. The source 42 is located in the source region 40b. The drain 43 is located in the drain region 40c.

Specifically, the channel layer 20 and the barrier layer 30 form a heterojunction, and a channel with 2DEG is formed on a surface, close to the barrier layer 30, of the channel layer 20. When a semiconductor device is in off-state, the p-type semiconductor layer 50 may deplete the 2DEG at the channel to achieve enhanced device. The first hydrogen-rich layer 61 is located on a side, close to the drain region 40c, of the p-type semiconductor layer 50. A hydrogen concentration of the first hydrogen-rich layer 61 is greater than a hydrogen concentration of the p-type semiconductor layer 50. Therefore, compared with the p-type semiconductor layer, a resistivity of the first hydrogen-rich layer is higher, which can reduce leakage current on a side, close to the drain, of the gate in off-state, and reduce an electric field intensity on a side of the drain in on-state, thereby improving the reliability of a device.

Optionally, after forming the p-type semiconductor layer 50, hydrogen ions implantation, a hydrogen plasma treatment or reverse diffusion of hydrogen in SiN is performed on a side, close to the drain 43, of the p-type semiconductor layer 50, so that free Mg in the p-type semiconductor layer 50 is bonded with H, thereby reducing the p-type concentration and forming the first hydrogen-rich layer 61 with high resistivity.

It should be noted that the hydrogen concentration refers to a number of H atoms in a unit volume.

In an embodiment, FIG. 2 is a schematic structural diagram of a semiconductor structure according to another embodiment of the present disclosure. As shown in FIG. 2, the semiconductor structure further includes a second hydrogen-rich layer 62, located on a side, close to the source region 40b, of the p-type semiconductor layer 50. A hydrogen concentration of the second hydrogen-rich layer 62 is greater than the hydrogen concentration of the p-type semiconductor layer 50.

Specifically, the hydrogen concentration of the second hydrogen-rich layer 62 is greater than the hydrogen concentration of the p-type semiconductor layer 50. Compared with the p-type semiconductor layer 50, a resistivity of the first hydrogen-rich layer 61 and a resistivity of the second hydrogen-rich layer 62 are both higher, which can reduce the leakage current of the gate in off-state and the electric field intensity near the gate in on-state, thereby improving the reliability of a device.

Optionally, the first hydrogen-rich layer 61 and the second hydrogen-rich layer 62 are formed synchronously, and the hydrogen concentration of the first hydrogen-rich layer 61 is equal to the hydrogen concentration of the second hydrogen-rich layer 62. Optionally, the hydrogen concentration of the first hydrogen-rich layer 61 is greater than the hydrogen concentration of the second hydrogen-rich layer 62. Due to an electric field intensity of a side, close to the drain 43, of the gate 41 is greater, the hydrogen concentration of the first hydrogen-rich layer 61 is greater and a resistivity of the first hydrogen-rich layer is higher, the reliability of the device may be better improved.

In an embodiment, FIG. 3 is a schematic structural diagram of a semiconductor structure according to another embodiment of the present disclosure. As shown in FIG. 3, in a direction parallel to a plane of the substrate 10, a width L1 of the first hydrogen-rich layer 61 is greater than a width L2 of the second hydrogen-rich layer 62. Specifically, the width L1 of the first hydrogen-rich layer 61 is greater, that is, a high-resistance region close to a side of the drain 43 is greater, so that a leakage current of the gate in the off-state can be better reduced.

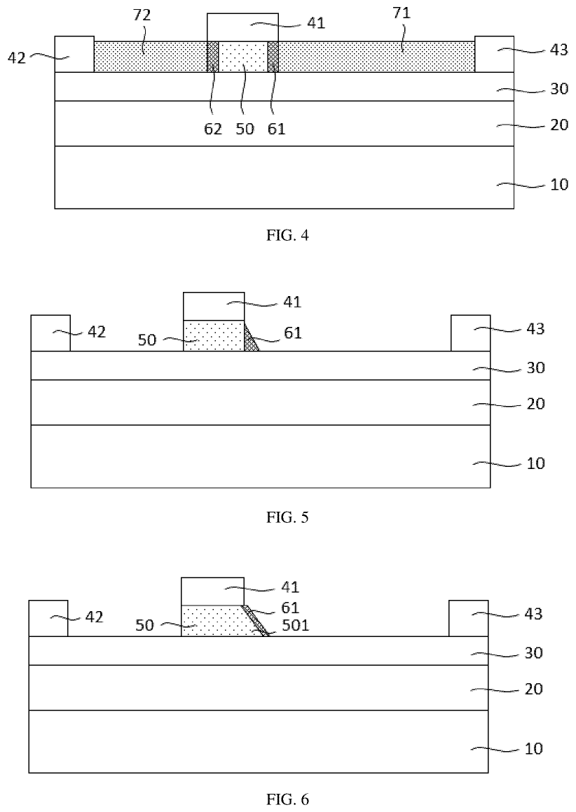

In an embodiment, FIG. 4 is a schematic structural diagram of a semiconductor structure according to another embodiment of the present disclosure. As shown in FIG. 4, the semiconductor structure further includes: a first passivation layer 71, located between a first hydrogen-rich layer 61 and a drain 43, and being in contact with the first hydrogen-rich layer 61. The first passivation layer 71 includes a hydrogenous material. Specifically, when the first hydrogen-rich layer 61 is manufactured, H in the first passivation layer 71 is reversely diffused into a p-type semiconductor layer 50, so that on a surface, close to the first passivation layer 71, of the p-type semiconductor layer 50, free Mg is bonded to the H, finally a high-resistance first hydrogen-rich layer 61 is formed between the p-type semiconductor layer 50 and the first passivation layer 71, which may reduce a leakage current of the gate in the off-state, and improve a reliability of the device better.

Optionally, the first passivation layer 71 includes SiN with a content of hydrogen ranging from 5% to 20%. Specifically, H in the SiN is reversely diffused into the p-type semiconductor layer 50. After H is bonded with the free Mg, the high-resistance first hydrogen-rich layer 61 is formed between the p-type semiconductor layer 50 and the SiN.

Optionally, as shown in FIG. 4, a second passivation layer 72 is disposed between the p-type semiconductor layer 50 and the source 42. The second passivation layer 72 includes SiN with a content of hydrogen ranging from 5% to 20%. The second hydrogen-rich layer 62 is formed between the p-type semiconductor layer 50 and the second passivation layer 72 while the first hydrogen-rich layer 61 is formed. Optionally, the first passivation layer 71 and the second passivation layer 72 are formed synchronously.

It should be noted that the content of hydrogen in SiN ranges from 5% to 20%. That is, a percentage of H atoms ranges from 5% and 20%.

In an embodiment, along a direction in which the gate 41 points to the drain 43, a thickness, in a direction perpendicular to a plane of the substrate, of the first hydrogen-rich layer 61 remains consistent or decreases. Optionally, as shown in FIG. 1, the thickness of the first hydrogen-rich layer 61 remains consistent.

Optionally, FIG. 5 is a schematic structural diagram of a semiconductor structure according to another embodiment of the present disclosure. As shown in FIG. 5, along the direction in which the gate 41 points to the drain 43, the thickness of the first hydrogen-rich layer 61 decreases. It can be understood that, closer to the barrier layer 30, a projection area, on the substrate 10, of the first hydrogen-rich layer 61 in high-resistance state gradually increases, which reduces a possible leakage current of the gate close to the barrier layer, and reduces an electric field intensity close to the barrier layer in on-state, thereby improving a reliability of a device. Optionally, the thickness of the first hydrogen-rich layer 61 decreases in a linear manner, a curved manner or a stepped manner. As shown in FIG. 5, the thickness of the first hydrogen-rich layer 61 decreases in the linear manner.

Optionally, in an embodiment that the semiconductor structure includes the second hydrogen-rich layer 62. Along the direction in which the gate 41 points to the source 42, the thickness, in the direction perpendicular to the plane of the substrate 10, of the second hydrogen-rich layer 62 remains consistent or decreases.

In an embodiment, FIG. 6 is a schematic structural diagram of a semiconductor structure according to another embodiment of the present disclosure. As shown in FIG. 6, the p-type semiconductor layer 50 includes a protruded structure 501 which is close to a side of the drain 43, and along a direction in which the gate 41 points to the drain 43, a thickness, in a direction perpendicular to a plane of the substrate, of the protruded structure 501 decreases. A shape of the first hydrogen-rich layer 61 is consistent with a shape of a side, close to the drain 43, of the p-type semiconductor layer 50.

Specifically, as shown in FIG. 6, the protruded structure 501 is of a p-type conductivity type. Because the thickness, in the direction perpendicular to the plane of the substrate 10, of the protruded structure 501 is reduced, the protruded structure 501 may deplete the 2DEG at a part of the channel, thereby reducing an electric field intensity of a side, close to the drain 43, of the gate 41 and further improving a breakdown voltage of the device.

Specifically, as shown in FIG. 6, the shape of the first hydrogen-rich layer 61 is consistent with the shape of the side, close to the drain 43, of the p-type semiconductor layer 50. A sidewall, close to the drain 43, of the protrusion structure 501 is linear, and a shape of a cross-section, perpendicular to the plane of the substrate 10, of the first hydrogen-rich layer 61 is linear.

Optionally, FIG. 7 is a schematic structural diagram of a semiconductor structure according to another embodiment of the present disclosure. As shown in FIG. 7, a sidewall, close to the drain 43, of the protruded structure 501 is of stepped shape, and a shape of a cross-section, perpendicular to the plane of the substrate 10, of the first hydrogen-rich layer 61 is of stepped shape.

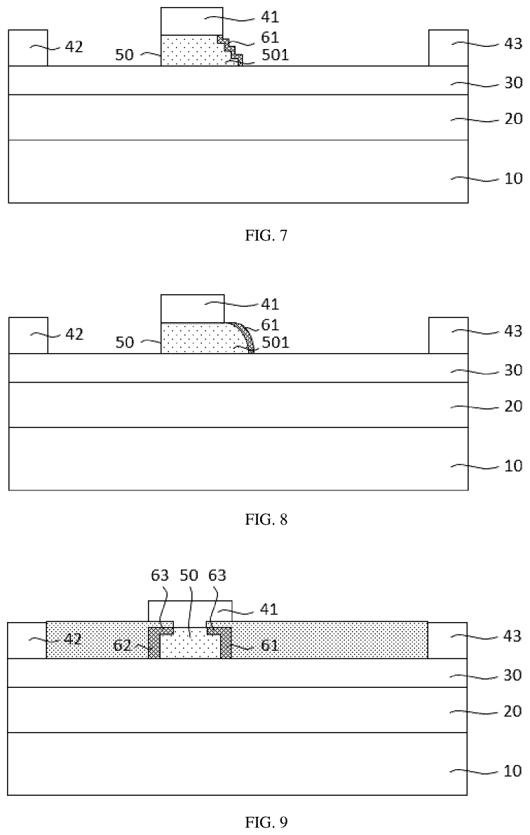

Optionally, FIG. 8 is a schematic structural diagram of a semiconductor structure according to another embodiment of the present disclosure. As shown in FIG. 8, a sidewall, close to the drain 43, of the protruded structure 501 is curved, and a shape of a cross-section, perpendicular to the plane of the substrate 10, of the first hydrogen-rich layer 61 is curved.

Optionally, in an embodiment that the semiconductor structure includes the second hydrogen-rich layer 62, a shape of the second hydrogen-rich layer 62 is consistent with a shape of a side, close to the source 42, of the p-type semiconductor layer 50.

In an embodiment, FIG. 9 is a schematic structural diagram of a semiconductor structure according to another embodiment of the present disclosure. As shown in FIG. 9, the semiconductor structure further includes: a third hydrogen-rich layer 63, covering a partial surface, away from the substrate 10, of the p-type semiconductor layer 50. The third hydrogen-rich layer 63 is connected to the first hydrogen-rich layer 61. Specifically, the first hydrogen-rich layer 61 and the third hydrogen-rich layer 63 cover a side surface of the p-type semiconductor layer 50 and partial upper surface of the p-type semiconductor layer 50, which enlarges an area of a high-resistance region, thereby reducing the leakage current the gate in off-state.

Optionally, in a side close to the source 42, the second hydrogen-rich layer 62 and the third hydrogen-rich layer 63 cover a side surface of the p-type semiconductor layer 50 and partial upper surface of the p-type semiconductor layer 50. The second hydrogen-rich layer 62 is connected to the third hydrogen-rich layer 63 on the side close to the source 42. Optionally, side surfaces of the p-type semiconductor layer 50 and partial upper surface of the p-type semiconductor layer 50 are covered with SiN containing hydrogen, and then the first hydrogen-rich layer 61, the second hydrogen-rich layer 62 and the third hydrogen-rich layer 63 are formed by annealing.

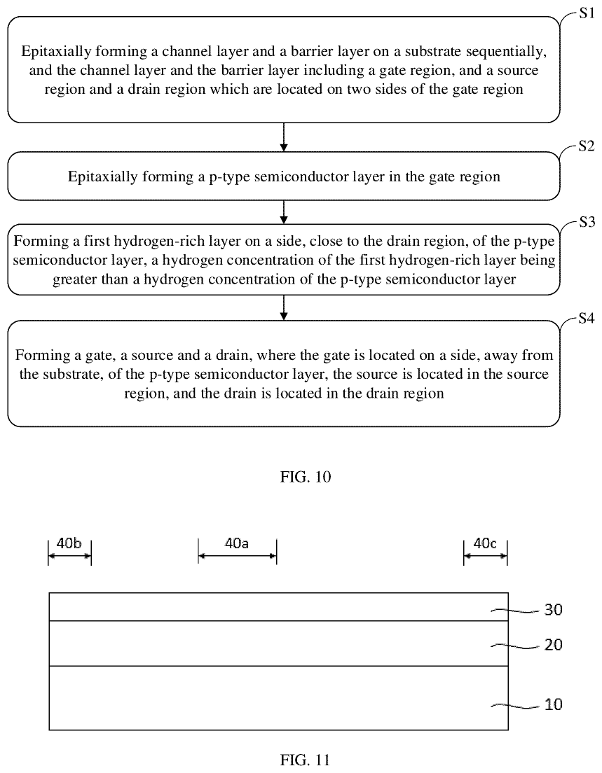

An embodiment of the present disclosure further provides a method for manufacturing a semiconductor structure. As shown in FIG. 10, the manufacturing method includes the following content.

Step S1, as shown in FIG. 11, epitaxially forming a channel layer 20 and a barrier layer 30 on a substrate 10 sequentially, the channel layer 20 and the barrier layer 30 including a gate region 40a, and a source region 40b and a drain region 40c which are located on two sides of the gate region 40a. Specifically, before epitaxially forming the channel layer 20, a nucleation layer and a buffer layer may be epitaxially formed on the substrate 10.

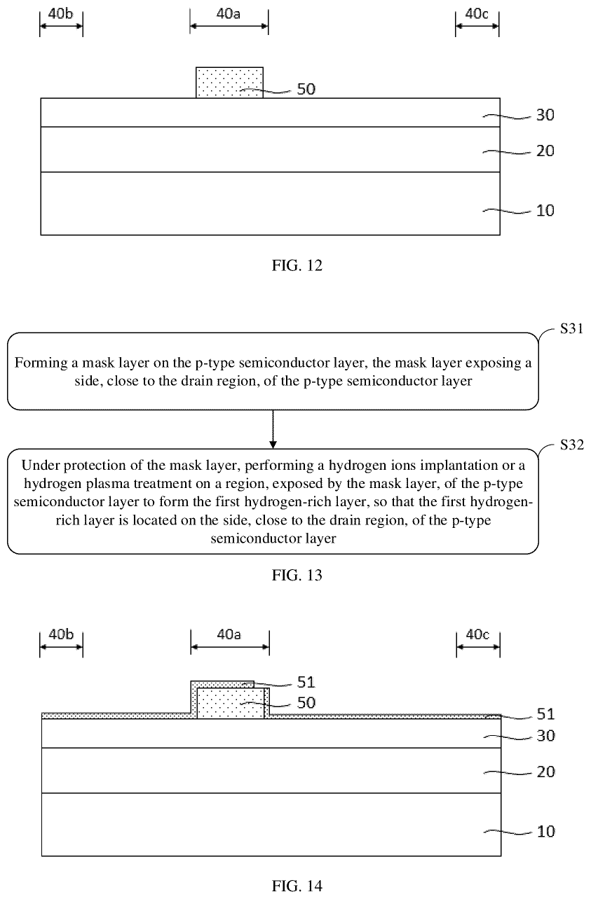

Step S2, as shown in FIG. 12, epitaxially forming a p-type semiconductor layer 50 in the gate region 40a. Specifically, a p-type doped semiconductor layer is epitaxially formed on the whole barrier layer 30, and after annealing activation and etching, the p-type semiconductor layer 50 is formed. Alternatively, the p-type doped semiconductor layer is epitaxially formed on the barrier layer 30, and after etching and annealing activation, the p-type semiconductor layer 50 is formed. Alternatively, a SiO₂ layer with an opening is formed on the barrier layer 30, and the opening exposes the gate region of the barrier layer. The p-type doped semiconductor layer is epitaxially formed in the opening, and a p-type semiconductor layer 50 is formed by annealing activation. The SiO₂ layer may be removed by etching.

Step S3, forming a first hydrogen-rich layer 61 on a side, close to the drain region 40c, of the p-type semiconductor layer 50, a hydrogen concentration of the first hydrogen-rich layer 61 being greater than a hydrogen concentration of the p-type semiconductor layer 50.

Optionally, as shown in FIG. 13, manufacturing the first hydrogen-rich layer 61 may include Step S31 and Step S32.

Step S31, as shown in FIG. 14, forming a mask layer 51 on the p-type semiconductor layer 50. The mask layer 51 exposes a side, close to the drain region 40c, of the p-type semiconductor layer 50. Optionally, the mask layer 51 may be formed by whole-surface deposition and etching. Optionally, a material of the mask layer 51 includes metal, SiN or AlN.

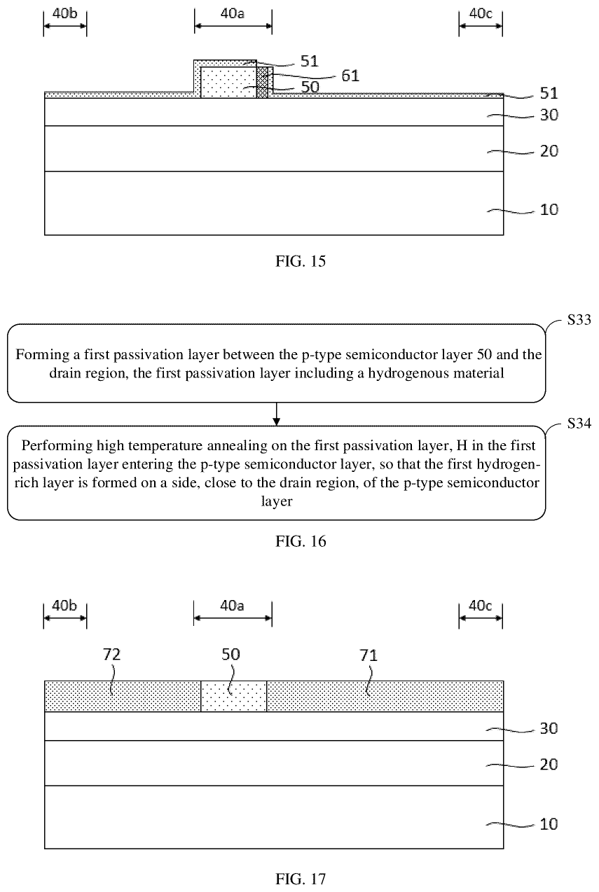

Step S32, as shown in FIG. 15, under protection of the mask layer 51, performing a hydrogen ions implantation or a hydrogen plasma treatment on a region, exposed by the mask layer 51, of the p-type semiconductor layer 50 to form the first hydrogen-rich layer 61, so that the first hydrogen-rich layer 61 is located on the side, close to the drain region 40c, of the p-type semiconductor layer 50. Specifically, hydrogen ions implantation or hydrogen plasma treatment may be performed to bond free Mg of the p-type semiconductor layer 50 with H, thereby reducing p-type concentration and forming the first hydrogen-rich layer 61 with high resistivity on the side, close to the drain region 40c, of the p-type semiconductor layer 50. Optionally, the mask layer 51 is etched and removed.

Optionally, as shown in FIG. 16, manufacturing the first hydrogen-rich layer 61 may include Step S33 and Step S34.

Step S33, as shown in FIG. 17, forming a first passivation layer 71 between the p-type semiconductor layer 50 and the drain region 40c. The first passivation layer 71 includes a hydrogenous material. Specifically, the first passivation layer 71 covers a side surface of the p-type semiconductor layer 50. Optionally, a second passivation layer 72 is formed between the p-type semiconductor layer 50 and the source region 40b. The second passivation layer 72 covers a side surface of the p-type semiconductor layer 50.

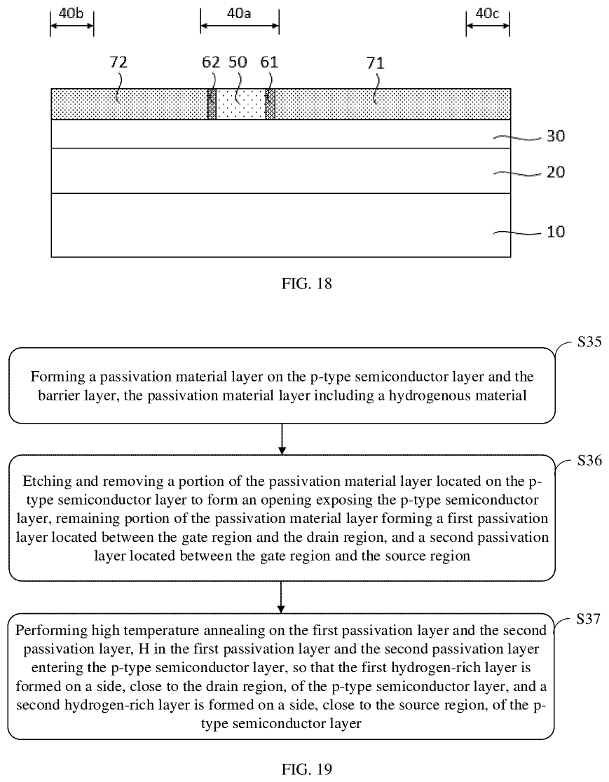

Step S34, as shown in FIG. 18, performing high temperature annealing on the first passivation layer 71. H in the first passivation layer 71 enters the p-type semiconductor layer 50, so that the first hydrogen-rich layer 61 is formed on a side, close to the drain region 40c, of the p-type semiconductor layer 50. Optionally, the first passivation layer 71 includes SiN with a content of hydrogen ranging from 5% to 20%. H in the SiN is reversely diffused into the p-type semiconductor layer 50, so that free Mg of the p-type semiconductor layer 50 is bonded with H again, thereby reducing the p-type concentration and forming the first hydrogen-rich layer 61 with high resistivity on the side, close to the drain region 40c, of the p-type semiconductor layer 50. Optionally, the second passivation layer 72 makes a second hydrogen-rich layer 62 formed on the side, close to the source region 40b, of the p-type semiconductor layer 50.

Optionally, a thickness of the first hydrogen-rich layer 61 ranges from 1 nm to 50 nm. The thickness refers to a distance that H in the first passivation layer 71 enters the p-type semiconductor layer 50.

Step S4, as shown in FIG. 1, forming a gate 41, a source 42 and a drain 43. The gate 41 is located on a side, away from the substrate 10, of the p-type semiconductor layer 50. The source 42 is located in the source region 40b. The drain 43 is located in the drain region 40c.

Optionally, in an intermediate structure formed in Step S32, the mask layer 51 is etched and removed first, and then the gate 41, the source 42 and the drain 43 are formed in the gate region 40a, the source region 40b and the drain region 40c, respectively. Optionally, in an intermediate structure formed in Step S34, the first passivation layer 71 in the drain region 40c and the second passivation layer 72 in the source region 40b are etched, until the barrier layer 30 or the channel layer 20 is exposed, and then the gate 41, the source 42 and the drain 43 are formed in the gate region 40a, the source region 40b and the drain region 40c, respectively.

Optionally, as shown in FIG. 19, forming the first hydrogen-rich layer 61, may include Step S35 to Step S37.

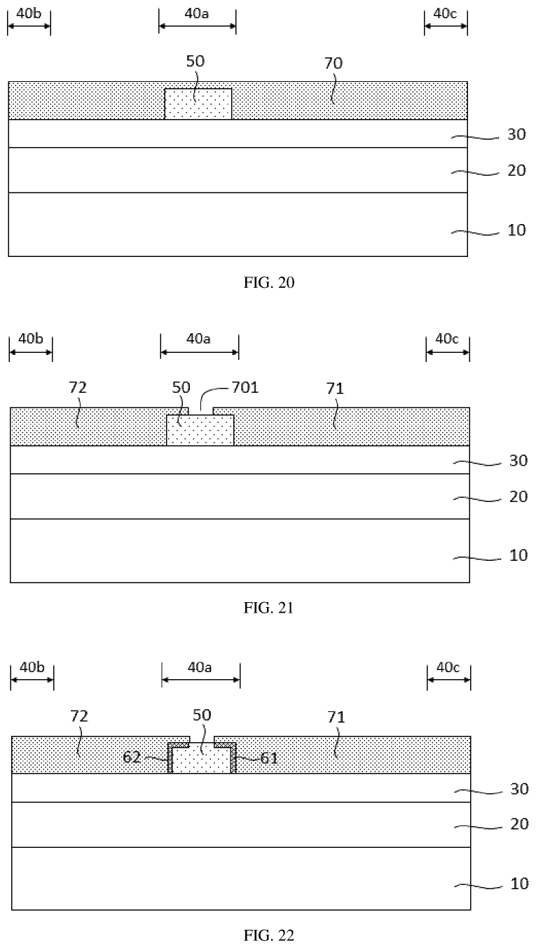

Step S35, as shown in FIG. 20, forming a passivation material layer 70 on the p-type semiconductor layer 50 and the barrier layer 30. The passivation material layer 70 includes a hydrogenous material. Optionally, a thicker passivation material layer 70 is formed, and then the passivation material layer 70 is chemically polished to form a flat upper surface. Optionally, the passivation material layer is conformally formed on the p-type semiconductor layer 50 (not shown in the figure).

Step S36, as shown in FIG. 21, etching and removing a portion of the passivation material layer 70 located on the p-type semiconductor layer 50 to form an opening 701 exposing the p-type semiconductor layer 50, remaining portion of the passivation material layer 70 forming a first passivation layer 71 located between the gate region 40a and the drain region 40c, and a second passivation layer 72 located between the gate region 40a and the source region 40b. Optionally, a patterned mask layer is formed on the passivation material layer 70 to etch and remove the portion of the passivation material layer 70.

Step S37, as shown in FIG. 22, performing high temperature annealing on the first passivation layer 71 and the second passivation layer 72, H in the first passivation layer 71 and H in the second passivation layer 72 enter the p-type semiconductor layer 50, so that the first hydrogen-rich layer 61 is formed on a side, close to the drain region 40c, of the p-type semiconductor layer 50, and a second hydrogen-rich layer 62 is formed on a side, close to the source region 40b, of the p-type semiconductor layer 50. Specifically, H diffusion principle may be referred to foregoing embodiments and not be repeated here.

Embodiments of the present disclosure provide a semiconductor structure and a method for manufacturing the same. The semiconductor structure includes: a substrate, a channel layer and a barrier layer which are stacked sequentially, the channel layer and the barrier layer including a gate region, and a source region and a drain region which are located on two sides of the gate region; a p-type semiconductor layer, located on the gate region to form an enhanced device; a first hydrogen-rich layer, located on a side, close to the drain region, of the p-type semiconductor layer, a hydrogen concentration of the first hydrogen-rich layer being greater than a hydrogen concentration of the p-type semiconductor layer. Compared with the p-type semiconductor layer, the first hydrogen-rich layer has a higher resistivity, which can reduce a leakage current on a side, close to the drain, of a gate in off-state, and reduce an electric field intensity on a side of the drain in on-state, thereby improving the reliability of a device.

Embodiments of the present disclosure provide the semiconductor structure and the method for manufacturing the same. The semiconductor structure includes: the substrate, the channel layer and the barrier layer which are stacked sequentially, the channel layer and the barrier layer including the gate region, and the source region and the drain region which are located on two sides of the gate region; the p-type semiconductor layer, located in the gate region to form an enhanced device; the first hydrogen-rich layer, located on the side, close to the drain region, of the p-type semiconductor layer. The hydrogen concentration of the first hydrogen-rich layer is greater than the hydrogen concentration of the p-type semiconductor layer. Compared with the p-type semiconductor layer, the first hydrogen-rich layer has a higher resistivity, which can reduce the leakage current on a side, close to the drain, of the gate in off-state, and reduce an electric field intensity on a side of the drain in on-state, thereby improving the stability of a device.

It is to be appreciated that the term “including” and variations thereof used in the present disclosure are open-ended, i.e., “including but not limited to”. The term “an embodiment” means “at least one embodiment”. In the specification, the specific features, structures, materials or characteristics described may be combined in a suitable manner in any one or more embodiments or examples. In addition, without contradicting each other, a person skilled in the art may combine and constitute different embodiments or examples described in this specification, and the features in different embodiments or examples.

What is claimed is:

1. A semiconductor structure, comprising:
a substrate, a channel layer and a barrier layer which are stacked sequentially, the channel layer and the barrier layer comprising a gate region, and a source region and a drain region which are located on two sides of the gate region;
a p-type semiconductor layer, located in the gate region;
a first hydrogen-rich layer, located on a side, close to the drain region, of the p-type semiconductor layer, a hydrogen concentration of the first hydrogen-rich layer being greater than a hydrogen concentration of the p-type semiconductor layer; and
a gate, a source and a drain, wherein the gate is located on a side, away from the substrate, of the p-type semiconductor layer, the source is located in the source region, and the drain is located in the drain region.

2. The semiconductor structure according to claim 1, further comprising:
a second hydrogen-rich layer, located on a side, close to the source region, of the p-type semiconductor layer, wherein a hydrogen concentration of the second hydrogen-rich layer is greater than the hydrogen concentration of the p-type semiconductor layer.

3. The semiconductor structure according to claim 2, wherein in a direction parallel to a plane of the substrate, a width of the first hydrogen-rich layer is greater than a width of the second hydrogen-rich layer.

4. The semiconductor structure according to claim 2, wherein along a direction in which the gate points to the source, a thickness, in a direction perpendicular to a plane of the substrate, of the second hydrogen-rich layer remains consistent or decreases.

5. The semiconductor structure according to claim 1, further comprising:
a first passivation layer, located between the first hydrogen-rich layer and the drain, and being in contact with the first hydrogen-rich layer,
wherein the first passivation layer comprises a hydrogenous material.

6. The semiconductor structure according to claim 5, wherein the first passivation layer comprises SiN with a content of hydrogen ranging from 5% to 20%.

7. The semiconductor structure according to claim 1, wherein along a direction in which the gate points to the drain, a thickness, in a direction perpendicular to a plane of the substrate, of the first hydrogen-rich layer remains consistent or decreases.

8. The semiconductor structure according to claim 7, wherein the thickness of the first hydrogen-rich layer decreases in a linear manner, a curved manner or a stepped manner.

9. The semiconductor structure according to claim 1, wherein the p-type semiconductor layer comprises a protruded structure which is close to a side of the drain, and along a direction in which the gate points to the drain, a thickness, in a direction perpendicular to a plane of the substrate, of the protruded structure decreases; and
a shape of the first hydrogen-rich layer is consistent with a shape of a side, close to the drain, of the p-type semiconductor layer.

10. The semiconductor structure according to claim 9, wherein a sidewall, close to the drain, of the protruded structure is linear, and a shape of a cross-section, perpendicular to the plane of the substrate, of the first hydrogen-rich layer is linear.

11. The semiconductor structure according to claim 9, wherein a sidewall, close to the drain, of the protruded structure is of a stepped shape, and a shape of a cross-section, perpendicular to the plane of the substrate, of the first hydrogen-rich layer is of a stepped shape.

12. The semiconductor structure according to claim 9, wherein a sidewall, close to the drain, of the protruded structure is curved, and a shape of a cross-section, perpendicular to the plane of the substrate, of the first hydrogen-rich layer is curved.

13. The semiconductor structure according to claim 1, further comprising:
a third hydrogen-rich layer, covering a partial surface, away from the substrate, of the p-type semiconductor layer, and connected to the first hydrogen-rich layer.

14. A method for manufacturing a semiconductor structure, comprising:
epitaxially forming a channel layer and a barrier layer on a substrate sequentially, the channel layer and the barrier layer comprising a gate region, and a source region and a drain region which are located on two sides of the gate region;
epitaxially forming a p-type semiconductor layer in the gate region;
forming a first hydrogen-rich layer on a side, close to the drain region, of the p-type semiconductor layer, a hydrogen concentration of the first hydrogen-rich layer being greater than a hydrogen concentration of the p-type semiconductor layer; and
forming a gate, a source and a drain, wherein the gate is located on a side, away from the substrate, of the p-type semiconductor layer, the source is located in the source region, and the drain is located in the drain region.

15. The method according to claim 14, wherein forming the first hydrogen-rich layer comprises:
forming a mask layer on the p-type semiconductor layer, the mask layer exposing a side, close to the drain region, of the p-type semiconductor layer; and
under protection of the mask layer, performing hydrogen ions implantation or a hydrogen plasma treatment on a region, exposed by the mask layer, of the p-type semiconductor layer to form the first hydrogen-rich layer, so that the first hydrogen-rich layer is located on a side, close to the drain region, of the p-type semiconductor layer.

16. The method according to claim 14, wherein forming the first hydrogen-rich layer comprises:
forming a first passivation layer between the p-type semiconductor layer and the drain region, the first passivation layer comprising a hydrogenous material; and
performing high temperature annealing on the first passivation layer, H in the first passivation layer entering the p-type semiconductor layer, so that the first hydrogen-rich layer is formed on a side, close to the drain region, of the p-type semiconductor layer.

17. The method according to claim 16, wherein the first passivation layer comprises SiN with a content of hydrogen ranging from 5% to 20%.

18. The method according to claim 14, wherein forming the first hydrogen-rich layer comprises:
forming a passivation material layer on the p-type semiconductor layer and the barrier layer, the passivation material layer comprising a hydrogenous material;
etching and removing a portion of the passivation material layer located on the p-type semiconductor layer to form an opening exposing the p-type semiconductor layer, remaining portion of the passivation material layer forming a first passivation layer located between the gate region and the drain region, and a second passivation layer located between the gate region and the source region; and
performing high temperature annealing on the first passivation layer and the second passivation layer, H in the first passivation layer and the second passivation layer entering the p-type semiconductor layer, so that the first hydrogen-rich layer is formed on a side, close to the drain region, of the p-type semiconductor layer, and a second hydrogen-rich layer is formed on a side, close to the source region, of the p-type semiconductor layer.

19. The method according to claim 18, wherein a hydrogen concentration of the second hydrogen-rich layer is greater than the hydrogen concentration of the p-type semiconductor layer.

20. The method according to claim 14, wherein a thickness of the first hydrogen-rich layer ranges from 1 nm to 50 nm.
